(19) United States
(12) Patent Application Publication
(10) Pub. No.: US 2026/0282505 A1
(43) Pub. Date: Sep. 17, 2026

(54) SEMICONDUCTOR DEVICE AND METHOD FOR MANUFACTURING SAME

(71) Applicant: Kioxia Corporation, Tokyo (JP)

(72) Inventors: Takahiro IHARA, Yokkaichi (JP); Ippei KUME, Yokkaichi (JP); Shinya ARAI, Yokkaichi (JP); Ayako KAWANISHI, Yokkaichi (JP)

(21) Appl. No.: 19/326,283

(22) Filed: Sep. 11, 2025

(30) Foreign Application Priority Data
Mar. 14, 2025 (JP) 2025-041338

(51) Int. Cl. H01L 23/00; H01L 25/18; H10B 80/00; H10D 80/30

(52) U.S. Cl. CPC H10D 80/30; H10B 80/00; H10W 90/00; H10W 72/019; H10W 72/01938; H10W 72/01951; H10W 72/923; H10W 72/9415; H10W 72/952; H10W 72/953; H10W 80/023; H10W 80/312; H10W 80/327; H10W 80/732; H10W 90/792

(57) ABSTRACT

According to one embodiment, a semiconductor device includes a first chip and a second chip, the first chip and the second chip being bonded to each other. The first chip includes a first insulating layer that is bonded to the second chip and via contact electrodes that extend in a first direction through the first insulating layer. The second chip includes a second insulating layer and wirings that have side surfaces in a second direction that are covered with the second insulating layer and are bonded to the via contact electrodes. In addition, in a region where the wiring and the via contact electrode overlap each other when viewed in the first direction, an insulating layer containing silicon (Si), carbon (C), and nitrogen (N) is provided between the wiring and the via contact electrode.

### CROSS-REFERENCE TO RELATED APPLICATION

This application is based upon and claims the benefit of priority from Japanese Patent Application No. 2025-041338, filed Mar. 14, 2025, the entire contents of which are incorporated herein by reference.

### FIELD

Embodiments described herein relate generally to a semiconductor device and a method for manufacturing the same.

### BACKGROUND

A semiconductor device including a first chip and a second chip, the first chip and the second chip being bonded to each other is known.

### DESCRIPTION OF THE DRAWINGS

FIG. 1 is a schematic exploded perspective view illustrating a configuration of a semiconductor device according to a first embodiment.

FIG. 2 is a schematic cross-sectional view illustrating a configuration of a part of a memory die.

FIG. 3 is a schematic cross-sectional view illustrating an enlarged part of FIG. 2.

FIG. 4 is a schematic cross-sectional view illustrating a structure of a bonding surface of the chips.

FIG. 5 is a schematic cross-sectional view illustrating another structure of the bonding surface of the chips.

FIG. 6 is a schematic cross-sectional view illustrating a method for manufacturing the semiconductor device according to the first embodiment.

FIG. 7 is a schematic cross-sectional view illustrating the same manufacturing method.

FIG. 8 is a schematic cross-sectional view illustrating the same manufacturing method.

FIG. 9 is a schematic cross-sectional view illustrating the same manufacturing method.

FIG. 10 is a schematic cross-sectional view illustrating the same manufacturing method.

FIG. 11 is a schematic cross-sectional view illustrating the same manufacturing method.

FIG. 12 is a schematic cross-sectional view illustrating the same manufacturing method.

FIG. 13 is a schematic cross-sectional view illustrating the same manufacturing method.

FIG. 14 is a schematic cross-sectional view illustrating the same manufacturing method.

FIG. 15 is a schematic cross-sectional view illustrating the same manufacturing method.

FIG. 16 is a schematic cross-sectional view illustrating the same manufacturing method.

FIG. 17 is a schematic cross-sectional view illustrating the same manufacturing method.

FIG. 18 is a schematic view illustrating the same manufacturing method.

FIG. 19 is a schematic view illustrating the same manufacturing method.

FIG. 20 is a schematic cross-sectional view illustrating a partial configuration of a semiconductor device according to a second embodiment.

FIG. 21 is a schematic cross-sectional view illustrating a partial configuration of a semiconductor device according to a third embodiment.

### DETAILED DESCRIPTION

In general, according to one embodiment, a semiconductor device includes a first chip and a second chip, the first chip and the second chip being bonded to each other. The first chip includes a first insulating layer that is bonded to the second chip, and a plurality of via contact electrodes that extend in a first direction through the first insulating layer at mutually different positions in a second direction intersecting the first direction. The second chip includes a second insulating layer and a plurality of wirings that are arranged in the second direction, extend in a third direction intersecting the first direction and the second direction, have side surfaces in the second direction that are covered with the second insulating layer, and are bonded to the plurality of via contact electrodes. An insulating layer containing silicon (Si), carbon (C), and nitrogen (N) is provided between a first wiring among the plurality of wirings and a first via contact electrode among the plurality of via contact electrodes in a region where the first wiring and the first via contact electrode overlap each other when viewed in the first direction.

Next, a semiconductor device and a method for manufacturing the same according to an embodiment will be described in detail with reference to the drawings. The following embodiment is merely an example, and is not intended to limit the present disclosure. In addition, the drawings below are schematic, and for convenience of description, some configurations and the like may be omitted. In addition, the same reference numerals will be assigned to common portions in a plurality of embodiments, and description thereof may be omitted.

In addition, when mentioned in the present specification, the term “semiconductor device” may mean a semiconductor storage device, or may mean a device other than the semiconductor storage device, such as an integrated circuit for calculation or an integrated circuit for communication.

In the present specification, when a first configuration is said to be “electrically connected” to a second configuration, the first configuration may be directly connected to the second configuration, or the first configuration may be connected to the second configuration through a wiring, a semiconductor member, a transistor, or the like. For example, when three transistors are connected in series, the first transistor is “electrically connected” to the third transistor even when the second transistor is in an OFF state.

In the present specification, a predetermined direction parallel to a surface of a substrate is referred to as an X direction, a direction which is parallel to the surface of the substrate and is perpendicular to the X direction is referred to as a Y direction, and a direction perpendicular to the surface of the substrate is referred to as a Z direction.

In the present specification, a direction intersecting a predetermined surface may be referred to as a first direction. In addition, a direction along the surface may be referred to as a second direction, and a direction that is along the surface and intersects the second direction may be referred to as a third direction. The first direction, the second direction, and the third direction may or may not coincide with any of the Z direction, the X direction, and the Y direction.

### First Embodiment

### Configuration of Semiconductor Device

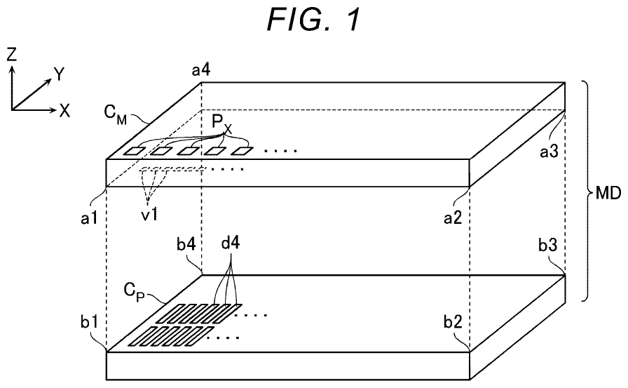

FIG. 1 is a schematic exploded perspective view illustrating a configuration of a semiconductor device according to a first embodiment. FIG. 1 illustrates a memory die MD as the semiconductor device. The memory die MD includes a chip C_{M} on a memory cell array side and a chip C_{P} on a peripheral circuit side.

A plurality of external pad electrodes P_{X} to which a bonding wire (not illustrated) may be connected are provided on the upper surface of the chip C_{M}. In addition, the lower ends of via contact electrodes v1 are provided on the lower surface of the chip C_{M}. In addition, a plurality of wirings d4 are provided in the vicinity of the upper surface of the chip C_{P}.

Hereinafter, regarding the chip C_{M}, the surface provided with the lower ends of the via contact electrodes v1 will be referred to as a front surface, and a surface provided with the plurality of external pad electrodes P_{X} will be referred to as a rear surface. In addition, regarding the chip C_{P}, the surface provided with the plurality of wirings d4 will be referred to as a front surface, and a surface on the opposite side of the front surface will be referred to as a rear surface. In the example illustrated in the drawings, the front surface of the chip C_{P} is provided above the rear surface of the chip C_{P}, and the front surface of the chip C_{M} is provided below the rear surface of the chip C_{M}.

The chip C_{M} and the chip C_{P} are disposed so that the front surface of the chip C_{M} faces the front surface of the chip C_{P}. The plurality of via contact electrodes v1 correspond to the plurality of wirings d4, respectively, and are disposed at positions where the plurality of via contact electrodes v1 can be bonded to the plurality of wirings d4, respectively. The via contact electrode v1 and the wiring d4 electrically connect the configuration in the chip C_{M} to the configuration in the chip C_{P}.

In the example of FIG. 1, corners a1, a2, a3, and a4 of the chip C_{M} correspond to corners b1, b2, b3, and b4 of the chip C_{P}, respectively.

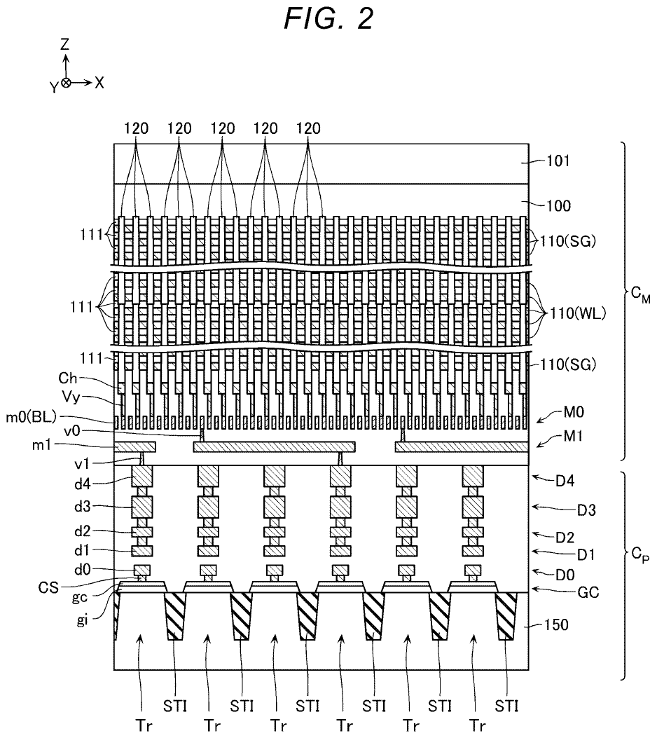

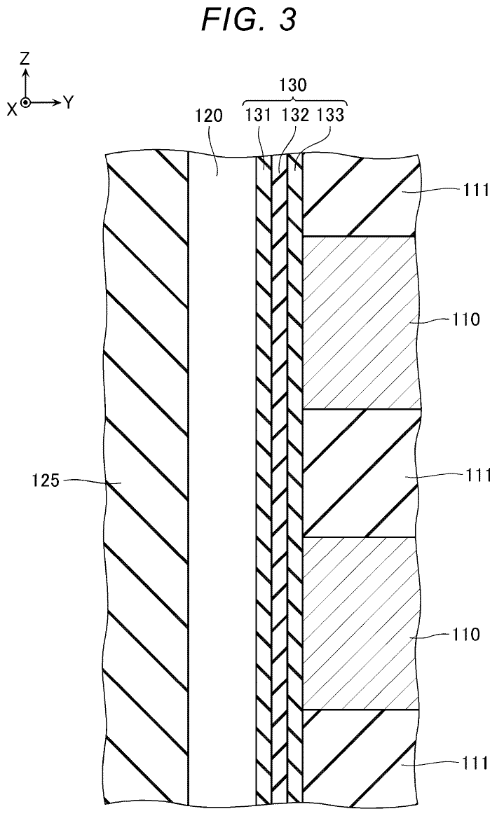

FIG. 2 is a schematic cross-sectional view illustrating a configuration of a part of the memory die MD. FIG. 3 is a schematic cross-sectional view illustrating an enlarged part of FIG. 2. Although FIG. 3 illustrates a YZ cross section, a structure similar to that in FIG. 3 is observed even when a cross section other than the YZ cross section (for example, an XZ cross section) along the central axis of a semiconductor column 120 is observed.

### Structure of Chip C_{M}

The chip C_{M} includes, for example, a plurality of conductive layers 110 and a plurality of insulating layers 111 alternately arranged in the Z direction, and semiconductor columns 120 extending in the Z direction through the plurality of conductive layers 110 and the plurality of insulating layers 111, as illustrated in FIG. 2. In addition, as illustrated in FIG. 3, a gate insulating film 130 is provided between the plurality of conductive layers 110 and the semiconductor column 120. In addition, a conductive layer 100 connected to the upper ends of the plurality of semiconductor columns 120 and an insulating layer 101 covering the upper surface of the conductive layer 100 are provided above the plurality of conductive layers 110 and the plurality of insulating layers 111. In addition, wiring layers M0 and M1 are provided below the plurality of conductive layers 110 and the plurality of insulating layers 111.

The conductive layer 110 has a substantially plate-like shape extending in the X direction. The conductive layer 110 may include a stacked film or the like of a barrier conductive film made of titanium nitride (TiN) or the like and a metal film made of tungsten (W) or the like. In addition, the conductive layer 110 may contain, for example, polycrystalline silicon containing impurities such as phosphorus (P) or boron (B).

In addition, among the plurality of conductive layers 110, one or a plurality of conductive layers 110 positioned in the uppermost layer and one or a plurality of conductive layers 110 positioned in the lowermost layer function as select gate lines SG of a NAND flash memory and gate electrodes of a plurality of select transistors connected to the select gate lines SG. The other conductive layers 110 mainly function as word lines WL of the NAND flash memory and gate electrodes of a plurality of memory cells (memory transistors) connected to the word lines WL.

The semiconductor columns 120 are arranged in a predetermined pattern in the X direction and the Y direction. The semiconductor columns 120 function as channel regions of the memory cells of the NAND flash memory and the select transistors. The semiconductor column 120 contains, for example, polycrystalline silicon (Si). Although not illustrated, impurity regions containing N-type impurities such as phosphorus (P) are provided at the upper end portion and the lower end portion of the semiconductor column 120. The semiconductor column 120 has a substantially cylindrical shape and has an insulating layer 125 (FIG. 3) made of silicon oxide or the like provided in the central portion.

The impurity region (not illustrated) at the lower end portion of the semiconductor column 120 is connected to a bit line BL through via contact electrodes Ch and Vy. The via contact electrodes Ch and Vy may include, for example, a stacked film of a barrier conductive film such as titanium nitride (TiN) and a metal film such as tungsten (W). The via contact electrodes Ch and Vy extend in the Z direction.

The gate insulating film 130 (FIG. 3) has a substantially cylindrical shape that covers the outer peripheral surface of the semiconductor column 120. For example, as illustrated in FIG. 3, the gate insulating film 130 includes a tunnel insulating film 131, a charge storage film 132, and a block insulating film 133, which are stacked between the semiconductor column 120 and the conductive layers 110. The tunnel insulating film 131 and the block insulating film 133 contain, for example, silicon oxide (SiO₂). The charge storage film 132 includes, for example, a film capable of storing charges such as silicon nitride (SiN). The tunnel insulating film 131, the charge storage film 132, and the block insulating film 133 have a substantially cylindrical shape, and extend in the Z direction along the outer peripheral surface of the semiconductor column 120 excluding a contact portion between the semiconductor column 120 and the conductive layer 100.

FIG. 3 shows an example in which the gate insulating film 130 includes the charge storage film 132 made of silicon nitride or the like. Meanwhile, the gate insulating film 130 may also include a floating gate made of, for example, polycrystalline silicon or the like containing N-type or P-type impurities.

The conductive layer 100 (FIG. 2) may include, for example, a semiconductor layer made of silicon (Si) or the like into which an N-type impurity such as phosphorus (P) is implanted, may contain a metal such as tungsten (W), or may contain a silicide such as tungsten silicide (WSi). The conductive layer 100 functions as a source line of the NAND flash memory.

The insulating layer 101 includes, for example, an insulating layer portion made of silicon oxide (SiO₂) or the like that covers the upper surface of the conductive layer 100 and a passivation layer portion that contains a resin material such as polyimide formed in the upper layer portion and is formed in the upper surface of the chip C_{M}. In addition, although not illustrated, the insulating layer 101 may include a rear surface wiring layer including a plurality of wirings. The plurality of wirings may contain, for example, aluminum (Al). In addition, a part of the plurality of wirings may function as the external pad electrodes P_{X} described with reference to FIG. 1.

The wiring layer M0 includes a plurality of wirings m0. The plurality of wirings m0 may include, for example, a stacked film of a barrier conductive film made of titanium nitride (TiN) or the like and a metal film made of copper (Cu) or the like. The plurality of wirings m0 mainly function as the bit lines BL. The bit lines BL are, for example, arranged in the X direction and extend in the Y direction.

The wiring layer M1 includes a plurality of wirings m1. The plurality of wirings m1 may include, for example, a stacked film of a barrier conductive film made of titanium nitride (TiN) or the like and a metal film made of tungsten (W) or the like. The plurality of wirings m1 are mainly arranged in the Y direction and extend in the X direction.

A plurality of via contact electrodes v0 are provided between the wiring layer M0 and the wiring layer M1. The plurality of via contact electrodes v0 may include a stacked film or the like of a barrier conductive film made of titanium nitride (TiN) or the like and a metal film made of tungsten (W) or the like. The plurality of via contact electrodes v0 extend in the Z direction and are connected to one of the plurality of wirings m0 and one of the plurality of wirings m1.

A plurality of via contact electrodes v1 are provided between the wiring layer M1 and the chip C_{P}. The plurality of via contact electrodes v1 may include a stacked film or the like of a barrier conductive film made of titanium nitride (TiN) or the like and a metal film made of copper (Cu) or the like. The plurality of via contact electrodes v1 extend in the Z direction and are connected to one of the plurality of wirings m1 and one of the plurality of wirings d4, which will be described below, in the chip C_{P}.

### Structure of Chip C_{P}

The chip C_{P} includes a semiconductor substrate 150, electrode layers GC provided above the semiconductor substrate 150, and wiring layers D0, D1, D2, D3, and D4 provided above the electrode layers GC.

The semiconductor substrate 150 contains, for example, P-type silicon (Si) containing a P-type impurity such as boron (B). The surface of the semiconductor substrate 150 is provided with, for example, an N-type well region containing N-type impurities such as phosphorus (P), a P-type well region containing P-type impurities such as boron (B), a semiconductor substrate region in which neither N-type well region nor the P-type well region are provided, and the like. The N-type well region, the P-type well region, and the semiconductor substrate region function as channel regions of a plurality of transistors Tr configuring a peripheral circuit, electrodes on one side of a plurality of capacitors, and the like. In addition, insulating regions STI made of silicon oxide (SiO₂), and the like are provided on the surface of the semiconductor substrate 150.

Electrode layers GC are provided on the surface of the semiconductor substrate 150 through insulating layers gi made of silicon oxide (SiO₂) or the like. The electrode layers GC include a plurality of electrodes gc facing the surface of the semiconductor substrate 150 in the Z direction. In addition, the individual regions of the semiconductor substrate 150 and the plurality of electrodes gc in the electrode layers GC are connected to via contact electrodes CS. The plurality of electrodes gc functions as gate electrodes of the plurality of transistors Tr configuring the peripheral circuit, electrodes on the other side of the plurality of capacitors, and the like, respectively.

The via contact electrode CS extends in the Z direction and is connected to the upper surface of the semiconductor substrate 150 or the upper surface of the electrode gc at the lower end. An impurity region containing an N-type impurity or a P-type impurity is provided at a connection portion between the via contact electrode CS and the semiconductor substrate 150. The via contact electrode CS may include, for example, a stacked film of a barrier conductive film made of titanium nitride (TiN) or the like and a metal film made of tungsten (W) or the like.

The wiring layers D0, D1, and D2 include a plurality of wirings d0, d1, and d2, respectively. The plurality of wirings d0, d1, and d2 may include, for example, a stacked film of a barrier conductive film made of titanium nitride (TiN) or the like and a metal film made of tungsten (W) or the like.

The wiring layers D3 and D4 include a plurality of wirings d3 and d4, respectively. The plurality of wirings d3 and d4 may include, for example, a stacked film of a barrier conductive film made of titanium nitride (TiN) or the like and a metal film made of copper (Cu) or the like. The wirings d0, d1, d2, d3, and d4 are appropriately connected to each other through a plurality of via contact electrodes provided in accordance with a circuit design in the semiconductor device. The wirings d4 in the wiring layer D4 are mainly arranged in the X direction and extend in the Y direction.

### Structure in Bonding Surface of Chips C_{M} and C_{P}

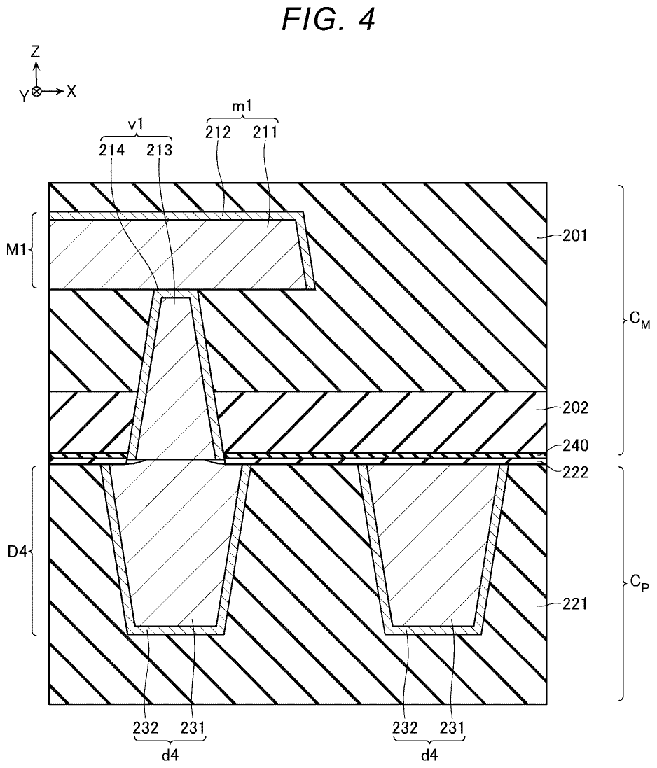

FIG. 4 is a schematic cross-sectional view illustrating a structure of the bonding surface of the chips C_{M} and C_{P}. FIG. 4 illustrates an enlarged part of FIG. 2.

The chip C_{M} includes an insulating layer 201 made of silicon oxide (SiO₂) or the like embedded in a height range including the wiring layer M1, and an insulating layer 202 made of silicon carbonitride (SiCN) or the like provided on the lower surface of the insulating layer 201. In the chip C_{M}, the via contact electrode v1 extends in the Z direction through a part of the insulating layer 201 and the insulating layer 202, and is connected to the wiring m1 at the upper end.

The chip C_{P} includes an insulating layer 221 made of silicon oxide (SiO₂) or the like embedded in a height range including the wiring layer D4. The lower surface, both side surfaces in the X direction, and both side surfaces in the Y direction of the wiring d4 are covered with the insulating layer 221. In addition, in the present embodiment, the surfaces of the insulating layer 221 and the wiring d4 are covered with the insulating layer 222 made of silicon carbonitride (SiCN) or the like, except for a region where the via contact electrode v1 and the wiring d4 overlap each other when viewed in the Z direction.

In addition, in the present embodiment, an insulating layer 240 made of silicon oxide (SiO₂) or the like is provided in the bonding surface between the insulating layer 202 and the insulating layer 222.

In addition, in the present embodiment, the wiring m1 includes a metal layer 211 made of tungsten (W) or the like and a barrier conductive layer 212 made of titanium nitride (TiN) or the like that covers the upper surface, both side surfaces in the X direction, and both side surfaces in the Y direction of the metal layer 211. The via contact electrode v1 includes a metal layer 213 made of copper (Cu) or the like and a barrier conductive layer 214 made of titanium nitride (TiN) or the like that covers the upper surface and outer peripheral surface of the metal layer 213. The wiring d4 includes a metal layer 231 made of copper (Cu) or the like, and a barrier conductive layer 232 made of titanium nitride (TiN) or the like that covers the lower surface, both side surfaces in the X direction, and both side surfaces in the Y direction of the metal layer 231.

Here, the metal layers 213 and 231 are integrated by bonding, and it becomes difficult to check the boundary therebetween. However, it is possible to check the bonding structure based on, for example, the shapes of the via contact electrode v1 and the wiring d4. For example, the dispositions of the via contact electrode v1 and the wiring d4 in the XY cross section are different. In addition, when the via contact electrode v1 and the wiring d4 are formed by a damascene method, each side surface (outer peripheral surface) has a tapered shape. Therefore, in the shape of a cross section along the Z direction of a portion where the via contact electrode v1 and the wiring d4 are bonded to each other, the side wall is not linear, and the shape of the cross section is a non-rectangular shape. In addition, when the via contact electrode v1 and the wiring d4 are bonded to each other, the bottom surfaces, the side surfaces (outer peripheral surfaces), and the upper surfaces of the metal layers 213 and 231 forming the via contact electrode v1 and the wiring d4 are covered with a barrier metal. In contrast, in a wiring layer for which general Cu is used, an insulating layer (SiN, SiCN, or the like) having a function of preventing the oxidation of Cu is provided on the upper surface of Cu, and a barrier metal is not provided. Therefore, it is possible to distinguish the wiring layer from a general wiring layer even when no bonding position misalignment occurs. Furthermore, the barrier conductive layers 214 and 232 are formed discontinuously.

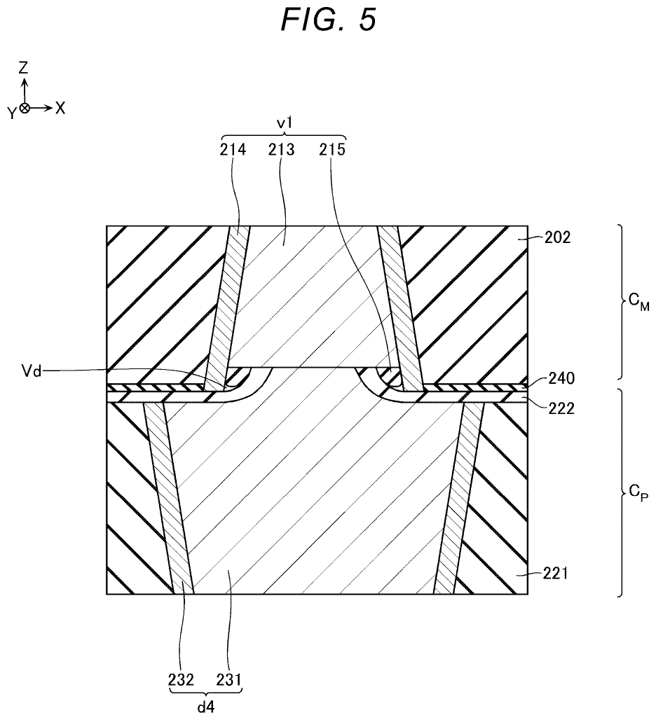

FIG. 5 is a schematic cross-sectional view illustrating another structure of the bonding surface of the chips C_{M} and C_{P}. FIG. 5 illustrates an enlarged part of FIG. 4.

As illustrated in FIG. 5, a region where the via contact electrode v1 and the wiring d4 overlap each other when viewed in the Z direction includes a region where the metal layer 213 and the metal layer 231 are bonded to each other and a region where the metal layer 213 and the metal layer 231 are separated from each other. In the region where the metal layer 213 and the metal layer 231 are separated from each other, a part of the insulating layer 222 formed along the upper surface of the metal layer 231 and an insulating member 215 made of copper oxide (CuO) or the like that is in contact with the lower surface of the metal layer 213, the barrier conductive layer 214, and the upper surface of the insulating layer 222 are provided. In addition, in the example illustrated in the drawing, a void Vd is formed in the region where the metal layer 213 and the metal layer 231 are separated from each other.

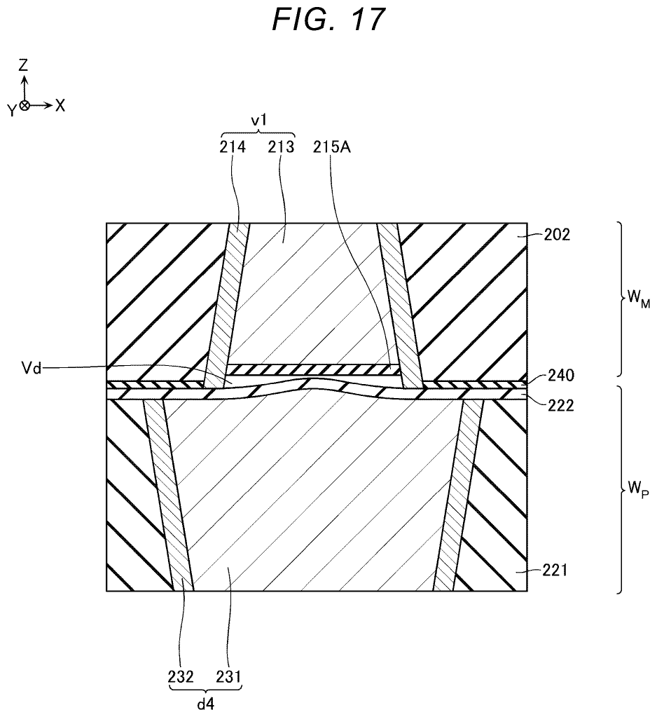

In addition, as described below with reference to FIG. 17 and the like, when the semiconductor device according to the present embodiment is manufactured, the metal layer 231 breaks through the insulating layer 222 and thermally expands. Therefore, the thickness of the insulating layer 222 in the Z direction has a size that is small enough to be broken through by the thermal expansion of the metal layer 231. The thickness of the insulating layer 222 in the Z direction is, for example, 5 nm or less.

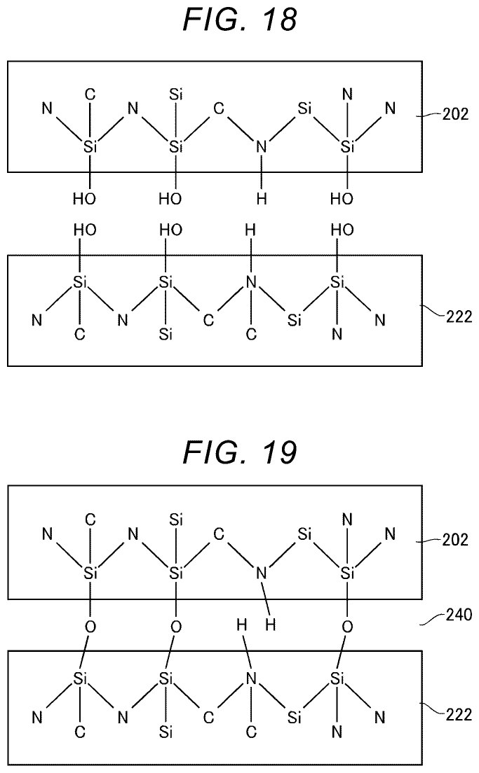

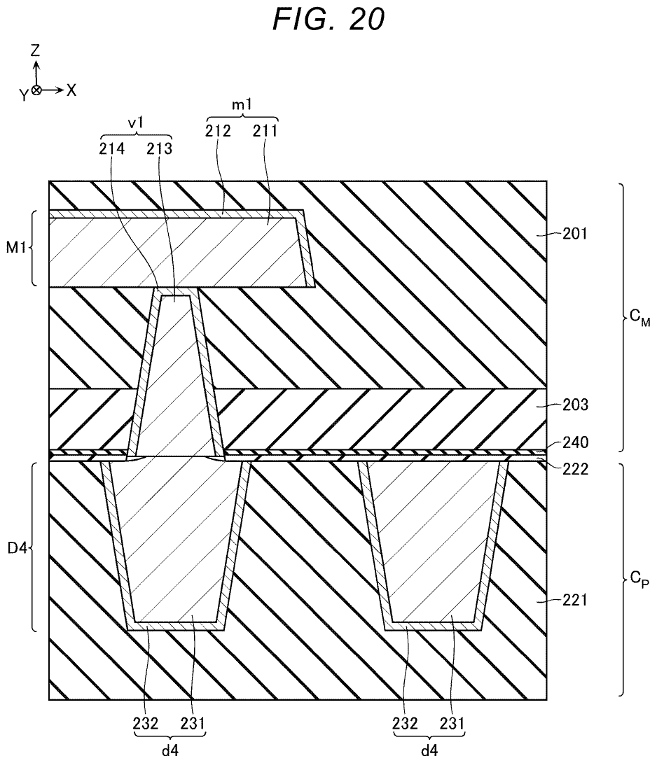

In addition, as described below with reference to FIG. 18 and FIG. 19, the insulating layer 240 is a layer generated by dehydration condensation of the insulating layers 202 and 222.

Here, the material or the like of each configuration can be detected by various methods such as electron energy-loss spectroscopy (EELS). When the resolution of EELS or the like is sufficiently high, it is possible to observe that the insulating layer 222 contains silicon (Si), carbon (C), and nitrogen (N). In addition, it is possible to observe that oxygen (O) is contained in a region between the insulating layer 222 and the insulating layer 202 and that oxygen (O) is not contained in the insulating layers 222 and 202 or the concentration of oxygen (O) contained in the insulating layers 222 and 202 is lower than the concentration of oxygen (O) contained in the region between the insulating layer 222 and the insulating layer 202. On the other hand, when the resolution of EELS or the like is not sufficiently high, it is also conceivable that the insulating layers 222 and 240 are observed as one insulating layer containing silicon (Si), carbon (C), nitrogen (N), and oxygen (O).

### Manufacturing Method

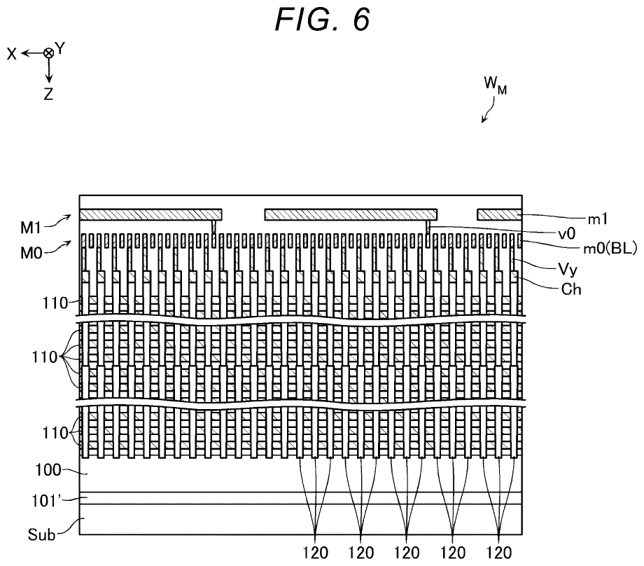

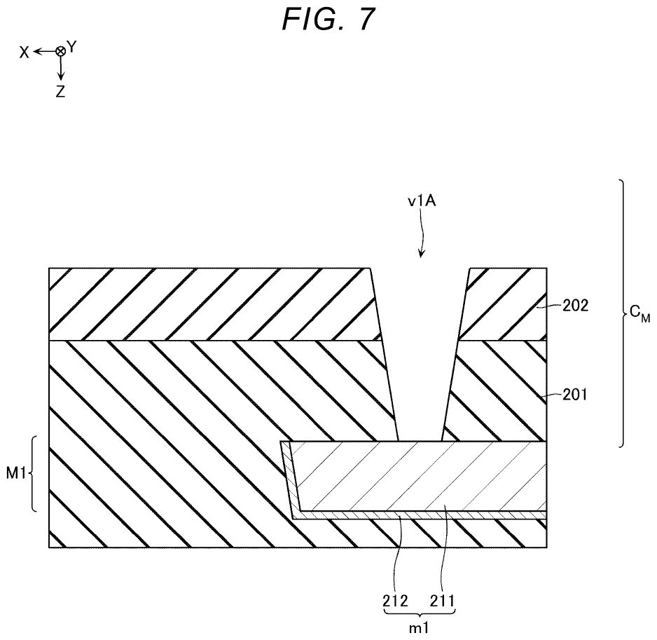

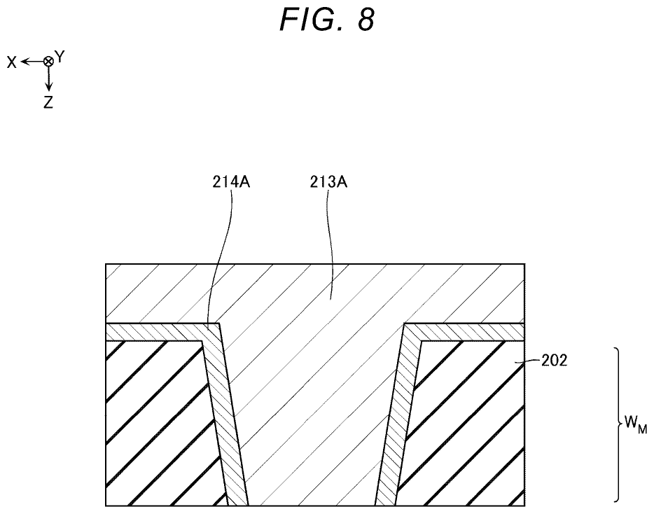

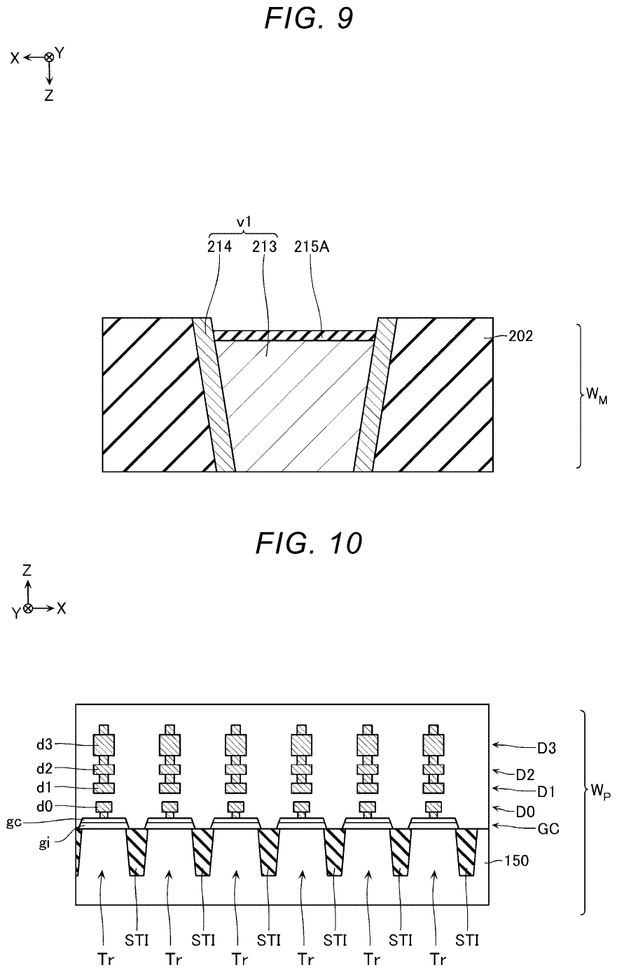

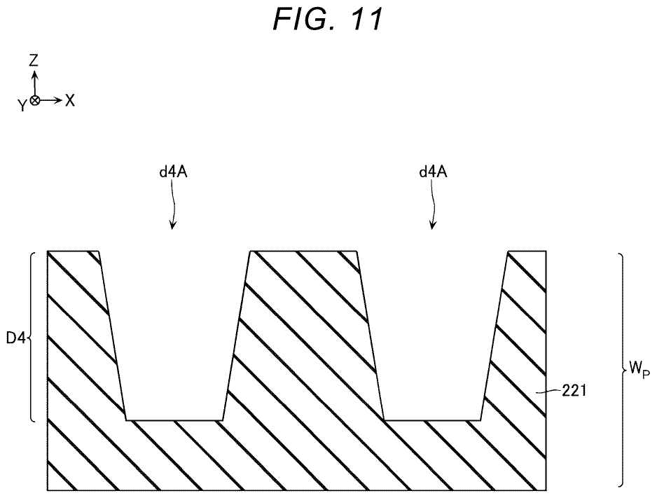

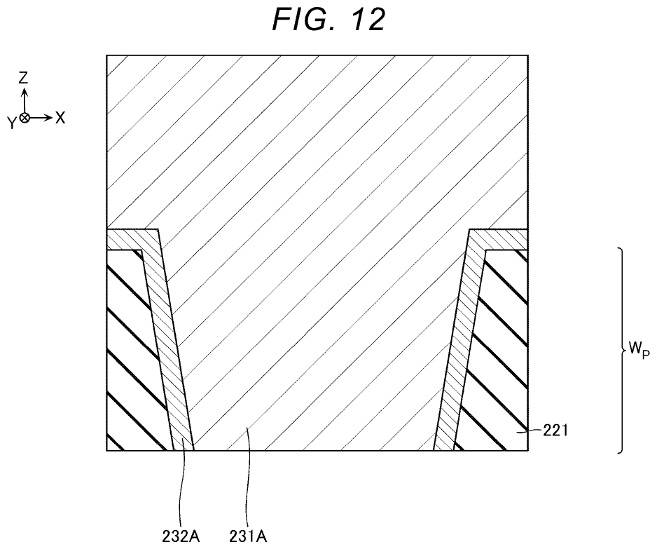

Next, a method for manufacturing the semiconductor device according to the first embodiment will be described with reference to FIG. 6 to FIG. 19. FIG. 6 and FIG. 10 are schematic cross-sectional views illustrating the same manufacturing method and illustrate a configuration corresponding to FIG. 2. FIG. 7 and FIG. 11 are schematic cross-sectional views illustrating the same manufacturing method and illustrate a configuration corresponding to FIG. 4. FIG. 8, FIG. 9, and FIG. 12 to FIG. 17 are schematic cross-sectional views illustrating the same manufacturing method and show a configuration corresponding to FIG. 5. FIG. 18 and FIG. 19 are schematic views illustrating the same manufacturing method.

In manufacturing the semiconductor device according to the present embodiment, first, a wafer W_{M} is prepared. The wafer W_{M} includes a substrate Sub and an insulating layer 101′ made of silicon oxide (SiO₂) formed on the surface of the substrate Sub as illustrated in FIG. 6. In addition, a configuration that is substantially the same as the configuration in the chip C_{M} is formed above the insulating layer 101′. However, the wafer W_{M} exemplified in FIG. 6 does not include the via contact electrode v1. In addition, the wafer W_{M} is a configuration before dicing.

Next, a contact hole v1A is formed at a position corresponding to the via contact electrode v1 as illustrated in FIG. 7. The contact hole v1A extends in the Z direction through the insulating layer 202 and a part of the insulating layer 201 and exposes a part of the surface of the wirings m1. This step is performed by, for example, a method such as reactive ion etching (RIE).

Next, a barrier conductive layer 214A and a metal layer 213A are formed in the contact hole v1A and on the surface of the insulating layer 202 as illustrated in FIG. 8. This step is performed by, for example, a method such as chemical vapor deposition (CVD).

Next, the parts of the barrier conductive layer 214A and the metal layer 213A formed in the contact hole v1A are left, and the parts formed on the surface of the insulating layer 202 are removed as illustrated in FIG. 9. Thereby, the via contact electrode v1 is formed. This step is performed by, for example, a method such as chemical mechanical polishing (CMP). In this step, the surface of the metal layer 213 is formed in a recessed shape with respect to the surface of the insulating layer 202. In addition, an insulating layer 215A made of copper oxide (CuO) or the like is formed on the upper surface of the metal layer 213.

Next, a plasma treatment is performed on the surface of the wafer W_{M} using, for example, oxygen (O₂) or nitrogen (N₂), and a dangling bond is formed on the surface of the insulating layer 202.

In addition, in manufacturing the semiconductor device according to the present embodiment, a wafer W_{P} is prepared. A configuration that is substantially the same as the configuration in the chip C_{P} is formed in the wafer W_{P} as illustrated in FIG. 10. However, the wafer W_{P} exemplified in FIG. 10 does not include the wirings d4. In addition, the wafer W_{P} is a configuration before dicing.

Next, grooves d4A are formed at positions corresponding to the wirings d4 as illustrated in FIG. 11. This step is performed by, for example, a method such as RIE.

Next, a barrier conductive layer 232A and a metal layer 231A are formed in the groove d4A and on the surface of the insulating layer 221 as illustrated in FIG. 12. This step is performed by, for example, a method such as CVD.

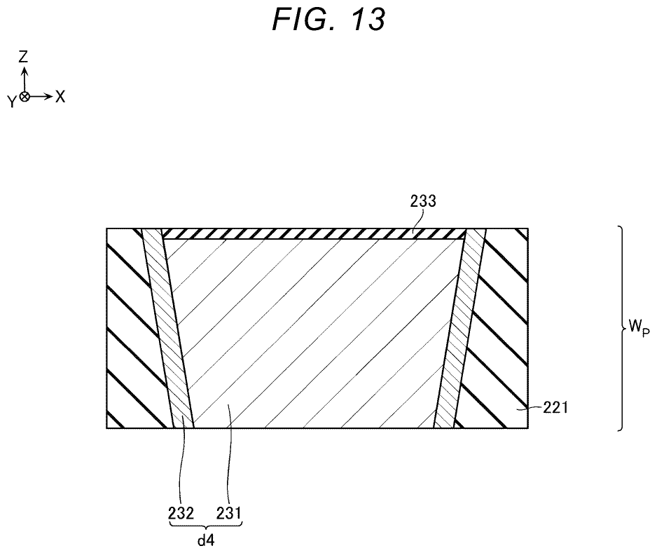

Next, the parts of the barrier conductive layer 232A and the metal layer 231A formed in the groove d4A are left, and the parts formed on the surface of the insulating layer 221 are removed as illustrated in FIG. 13. Thereby, the wiring d4 is formed. This step is performed by, for example, a method such as CMP. In this step, an insulating layer 233 made of copper oxide (CuO) or the like is formed on the upper surface of the metal layer 231.

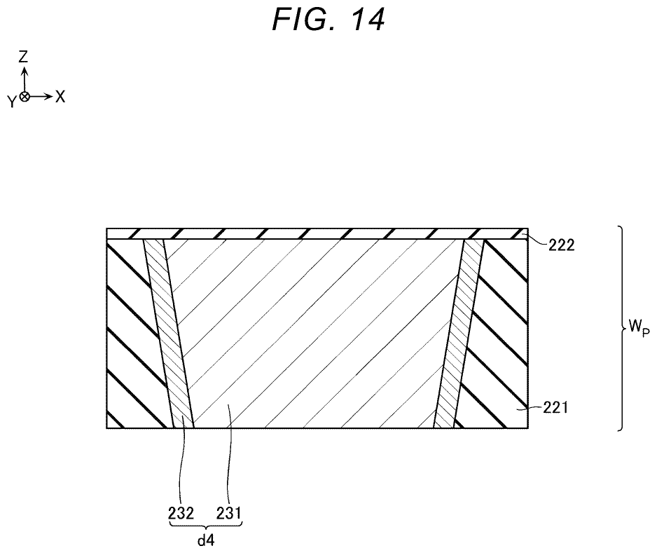

Next, the insulating layer 222 is formed on the surfaces of the insulating layer 221 and the wiring d4 as illustrated in FIG. 14. This step is performed by, for example, a plasma treatment or the like in which ammonia (NH₃) is used. In this step, the insulating layer 233 is reduced. In addition, in this step, a dangling bond is formed on the surface of the insulating layer 222.

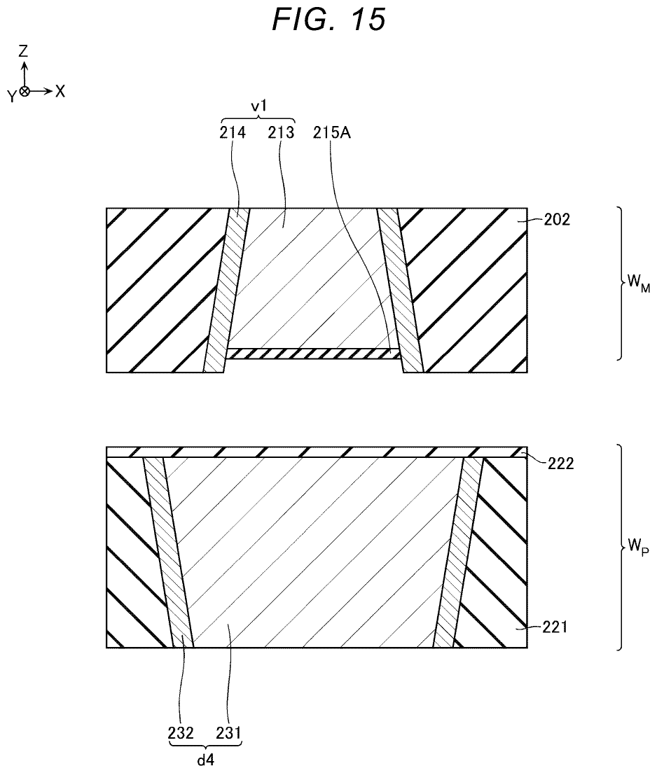

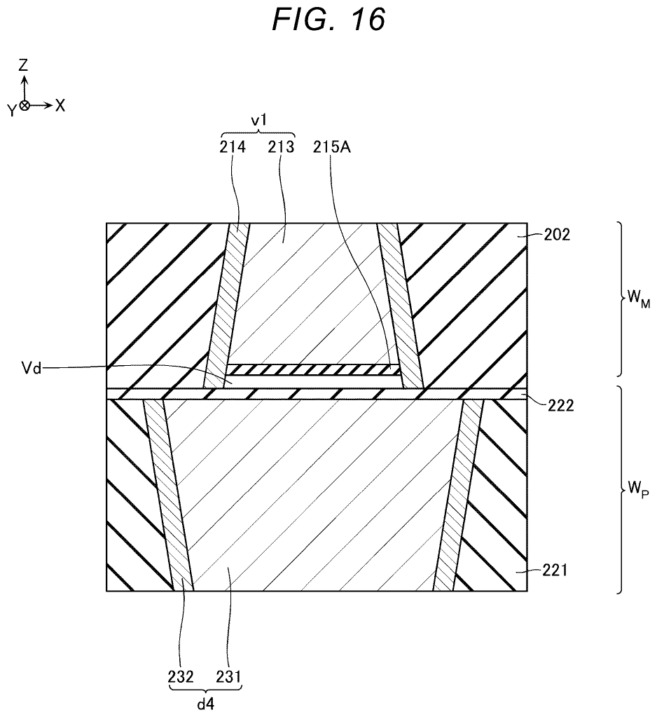

Next, the surface of the wafer W_{M} is made to face the surface of the wafer W_{P} as illustrated in FIG. 15, and the surface of the wafer W_{M} is brought into contact with the surface of the wafer W_{P} as illustrated in FIG. 16. Here, in the wafer W_{M}, as described above, a shape in which the surface of the metal layer 213 is recessed as compared with the surface of the insulating layer 202 is formed. Therefore, in a region where the via contact electrode v1 and the wiring d4 overlap each other when viewed in the Z direction, a void Vd is formed between the surface of the metal layer 213 and the surface of the insulating layer 222.

Next, a heat treatment is performed in a state where the surface of the wafer W_{M} and the surface of the wafer W_{P} are in contact with each other. Thereby, the insulating layer 240 is formed between the insulating layer 222 and the insulating layer 202, and the wafer W_{M} and the wafer W_{P} are bonded to each other as illustrated in FIG. 17.

Here, as described above, dangling bonds are formed on the surfaces of the insulating layers 222 and 202. This appearance is illustrated in FIG. 18. In the example of FIG. 18, a plurality of OH groups are formed in the silicon (Si) atoms in SiCN configuring the insulating layers 222 and 202. When the heat treatment is performed in this state, as illustrated in FIG. 19, dehydration condensation occurs between the OH group in the insulating layer 222 and the OH group in the insulating layer 202, and the silicon (Si) atoms are bonded to each other through the oxygen (O) atoms. The region where the silicon (Si) atoms are bonded to each other through the oxygen (O) atoms becomes the insulating layer 240.

In addition, in this step, thermal expansion occurs in the metal layer 231 as illustrated in FIG. 17. The metal layer 231 breaks through the insulating layer 215A and the insulating layer 222, expands, reaches and integrates with the metal layer 213 as illustrated in FIG. 5. The insulating layer 222 is pushed to a different region in the void Vd. Similarly, the insulating layer 215A is pushed to a different region in the void Vd and becomes the insulating member 215.

After this step, the insulating layer 101′ and the substrate Sub (FIG. 6) are removed, and the insulating layer 101 (FIG. 2) is formed. In addition, the structure in which the wafers W_{M} and W_{P} are bonded together is diced and individualized to become a plurality of memory dies MD.

### Effects

A semiconductor device including a first chip and a second chip, the first chip and the second chip being bonded to each other is known. In such a semiconductor device, for example, an insulating layer made of silicon oxide (SiO₂) or the like and a bonding electrode made of copper (Cu) or the like are provided in the bonding surface of the first chip and the second chip.

In such a semiconductor device, generally, the insulating layers provided in the bonding surface are bonded to each other, and the bonding electrodes provided in the bonding surface are bonded to each other. Therefore, from the viewpoint of the strength or reliability of bonding, the pattern of the bonding electrode in the first chip and the pattern of the bonding electrode in the second chip are often matched. On the other hand, omission of such bonding electrodes makes it possible to reduce the number of manufacturing steps and to achieve high integration of the semiconductor device.

Here, when the wiring d4 is formed by a method such as CMP as described with reference to FIG. 13, the insulating layer 233 made of copper oxide (CuO) or the like is formed on the surface of the metal layer 231 in the wiring d4. Here, the copper oxide (Cu) is not suitably bonded to the insulating layer made of silicon oxide (SiO₂). Therefore, when an attempt is made to bond such a wafer W_{P} as exemplified in FIG. 13 and such a wafer W_{M} as exemplified in FIG. 9 to each other, it is not possible to bond the wafer W_{P} and the wafer W_{M} to each other in regions corresponding to the wirings d4. Since the wirings d4 are disposed in the wiring layer D4 at a predetermined density, in such a case, there is a concern that a problem may occur in terms of mechanical strength. In addition, since it is not possible to make the wafer W_{P} and the wafer W_{M} suitably adhere to each other, there is a concern that metal atoms in the wirings d4 may diffuse and electromigration or the like may thus occur.

Therefore, in the present embodiment, the insulating layer 222 is formed on the surface of the wafer W_{P} as described with reference to FIG. 14. In addition, as described with reference to FIG. 17, when the wafer W_{M} and the wafer W_{P} are bonded to each other, the metal layer 231 breaks through the insulating layer 215A and the insulating layer 222, expands, reaches, and integrates with the metal layer 213.

According to such a method, it is possible to suitably bond the entire surface of the wafer W_{P} to the insulating layer 202 in the wafer W_{M} without providing a layer of the bonding electrode on the surface of the wafer W_{P}. This makes it possible to firmly bond the wafer W_{M} and the wafer W_{P}. In addition, since it is possible to make the wafer W_{M} and the wafer W_{P} suitably adhere to each other, it is possible to reduce the diffusion of the metal atoms in the wirings d4, and it is thereby possible to reduce the occurrence of electromigration or the like.

### Second Embodiment

In the first embodiment, the insulating layer 202 contains silicon carbonitride (SiCN). However, such a configuration is merely an example, and the material contained in the insulating layer 202 can be appropriately adjusted. Hereinafter, an example in which a configuration corresponding to the insulating layer 202 contains silicon nitride (SiN) will be described as a semiconductor device according to a second embodiment.

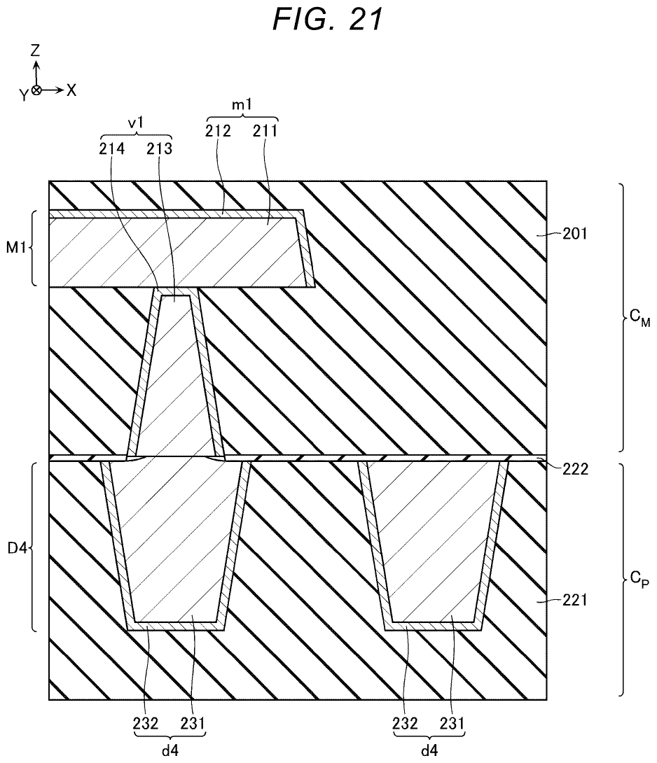

FIG. 20 is a schematic cross-sectional view illustrating a partial configuration of the semiconductor device according to the second embodiment. The semiconductor device according to the second embodiment is basically configured in the same manner as the semiconductor device according to the first embodiment. However, the semiconductor device according to the second embodiment includes an insulating layer 203 instead of the insulating layer 202. The insulating layer 203 is basically configured in the same manner as the insulating layer 202. However, the insulating layer 203 contains not silicon carbonitride (SiCN) but silicon nitride (SiN).

Even with such a configuration, the insulating layer 203 and the insulating layer 222 can be suitably bonded to each other by performing a plasma treatment on the surface of the wafer W_{M} and forming a dangling bond on the surface of the insulating layer 203.

### Third Embodiment

FIG. 21 is a schematic cross-sectional view illustrating a partial configuration of a semiconductor device according to a third embodiment. The semiconductor device according to the third embodiment is basically configured in the same manner as the semiconductor device according to the first embodiment. However, the semiconductor device according to the third embodiment does not include the insulating layer 202, and the insulating layer 201 is bonded to the insulating layer 222.

Even with such a configuration, the insulating layer 201 and the insulating layer 222 can be suitably bonded to each other by performing a plasma treatment on the surface of the wafer W_{M} and forming a dangling bond on the surface of the insulating layer 201.

Here, in the third embodiment as well, the material or the like of each configuration can be detected by various methods such as EELS in the same manner as in the first embodiment. However, the insulating layer 201 contains silicon oxide (SiO₂). Therefore, it is considered that even when the insulating layer 201 and the insulating layer 222 are bonded to each other by dehydration condensation, it is difficult to observe the insulating layer 240 generated by such bonding. However, in the present embodiment as well, when the resolution of EELS or the like is sufficiently high, it is possible to observe that carbon (C) and nitrogen (N) are contained in a region between the insulating layer 201 and the insulating layer 221 and that carbon (C) and nitrogen (N) are not contained in the insulating layers 201 and 221 or the concentrations of carbon (C) and nitrogen (N) contained in the insulating layer 201 and the insulating layer 221 are lower than the concentrations of carbon (C) and nitrogen (N) contained in the region between the insulating layer 201 and the insulating layer 221.

### Other Embodiments

In the first to third embodiments, examples in which the surfaces of the wirings d4 in the chip C_{P} on the peripheral circuit side are covered with the insulating layer 222 and the wirings d4 in the chip C_{P} on the peripheral circuit side and the via contact electrodes v1 in the chip C_{M} on the memory cell array side are bonded to each other are illustrated. However, such configurations are merely examples, and the specific configuration or the like can be adjusted as appropriate. For example, the surface of the wiring including copper (Cu) or the like in the chip C_{M} on the memory cell array side may be covered with the insulating layer 222, and this wiring in the chip C_{M} on the memory cell array side and the via contact electrode containing copper (Cu) or the like in the chip C_{P} on the peripheral circuit side may be bonded to each other.

In addition, in the first to third embodiments, the memory die MD (semiconductor storage device) has been exemplified as the semiconductor device. However, the above-described techniques can also be applied to semiconductor devices other than the semiconductor storage device.

### Others

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor device comprising:
a first chip; and
a second chip, the first chip and the second chip being bonded to each other,
wherein the first chip includes
a first insulating layer that is bonded to the second chip, and
a plurality of via contact electrodes that extend in a first direction through the first insulating layer at different positions in a second direction intersecting the first direction,
the second chip includes
a second insulating layer, and
a plurality of wirings that are arranged in the second direction, extend in a third direction intersecting the first direction and the second direction, have side surfaces in the second direction that are covered with the second insulating layer, and are bonded to the plurality of via contact electrodes, and
an insulating layer containing silicon (Si), carbon (C), and nitrogen (N) is provided between a first wiring among the plurality of wirings and a first via contact electrode among the plurality of via contact electrodes in a region where the first wiring and the first via contact electrode overlap each other when viewed in the first direction.

2. The semiconductor device according to claim 1,
wherein the plurality of wirings contain copper (Cu), and
an insulating member containing copper (Cu) and oxygen (O) is provided in the region where the first wiring and the first via contact electrode overlap each other when viewed in the first direction.

3. The semiconductor device according to claim 1,
wherein a void is provided in the region where the first wiring and the first via contact electrode overlap each other when viewed in the first direction.

4. The semiconductor device according to claim 1,
wherein the second chip further includes a third insulating layer that covers surfaces of the second insulating layer and the plurality of wirings on a first chip side in the first direction and contains silicon (Si), carbon (C), and nitrogen (N), and
the insulating layer provided in the region where the first wiring and the first via contact electrode overlap each other when viewed in the first direction is a part of the third insulating layer.

5. The semiconductor device according to claim 4,
wherein a thickness of the third insulating layer in the first direction is 5 nm or less.

6. The semiconductor device according to claim 4, further comprising:
a fourth insulating layer that is connected to the first insulating layer and the third insulating layer and contains oxygen (O).

7. The semiconductor device according to claim 6,
wherein the first insulating layer contains silicon (Si) and nitrogen (N), and
the first insulating layer does not contain oxygen (O), or a concentration of oxygen (O) in the first insulating layer is lower than a concentration of oxygen (O) in the fourth insulating layer.

8. The semiconductor device according to claim 7,
wherein the first insulating layer further contains carbon (C).

9. The semiconductor device according to claim 4,
wherein the first insulating layer contains silicon (Si) and oxygen (O), and
the first insulating layer does not contain carbon (C) and nitrogen (N), or concentrations of carbon (C) and nitrogen (N) in the first insulating layer are lower than concentrations of carbon (C) and nitrogen (N) in the third insulating layer.

10. A semiconductor device comprising:
a first chip; and
a second chip, the first chip and the second chip being bonded to each other,
wherein the first chip includes
a first insulating layer that is bonded to the second chip, and
a plurality of via contact electrodes that extend in a first direction through the first insulating layer at different positions in a second direction intersecting the first direction, and
the second chip includes
a second insulating layer,
a plurality of wirings that are arranged in the second direction, extend in a third direction intersecting the first direction and the second direction, have side surfaces in the second direction that are covered with the second insulating layer, and are bonded to the plurality of via contact electrodes, and
a third insulating layer that covers surfaces of the second insulating layer and the plurality of wirings on a first chip side in the first direction and contains silicon (Si), carbon (C), and nitrogen (N).

11. The semiconductor device according to claim 10,
wherein a thickness of the third insulating layer in the first direction is 5 nm or less.

12. The semiconductor device according to claim 10, further comprising:
a fourth insulating layer that is connected to the first insulating layer and the third insulating layer and contains oxygen (O).

13. The semiconductor device according to claim 12,
wherein the first insulating layer contains silicon (Si) and nitrogen (N), and
the first insulating layer does not contain oxygen (O), or a concentration of oxygen (O) in the first insulating layer is lower than a concentration of oxygen (O) in the fourth insulating layer.

14. The semiconductor device according to claim 13,
wherein the first insulating layer further contains carbon (C).

15. The semiconductor device according to claim 10,
wherein the first insulating layer contains silicon (Si) and oxygen (O), and
the first insulating layer does not contain carbon (C) and nitrogen (N), or concentrations of carbon (C) and nitrogen (N) in the first insulating layer are lower than concentrations of carbon (C) and nitrogen (N) in the third insulating layer.

16. A method for manufacturing a semiconductor device, the method comprising:
forming a plurality of contact holes that extend in a first direction at different positions in a second direction intersecting the first direction in a first insulating layer of a first wafer;
forming a first conductive layer on a surface of the first insulating layer and in the plurality of contact holes;
forming a plurality of via contact electrodes by removing a part of the first conductive layer formed on the surface of the first insulating layer by a first flattening treatment;
forming a plurality of grooves that are arranged in the second direction and extend in a third direction intersecting the first direction and the second direction in a second insulating layer of a second wafer;
forming a second conductive layer on a surface of the second insulating layer and in the plurality of grooves;
forming a plurality of wirings by removing a part of the second conductive layer formed on the surface of the second insulating layer by a second flattening treatment;
forming a third insulating layer containing silicon (Si), carbon (C), and nitrogen (N) on surfaces of the second insulating layer and the plurality of wirings of the second wafer; and
bonding a surface of the first wafer and a surface of the second wafer.

17. The method for manufacturing a semiconductor device according to claim 16, wherein forming the plurality of via contact electrodes comprises:
forming a surface of the first conductive layer in a recessed shape with respect to the surface of the first insulating layer by the first flattening treatment.

18. The method for manufacturing a semiconductor device according to claim 17,
wherein when the surface of the first wafer and the surface of the second wafer are bonded to each other, a void is formed between the surface of the first conductive layer and the surface of the second conductive layer.

19. The method for manufacturing a semiconductor device according to claim 16,
wherein before the surface of the first wafer and the surface of the second wafer are bonded to each other, a plasma treatment is performed on the surfaces of the first wafer and the second wafer.

20. The method for manufacturing a semiconductor device according to claim 19,
wherein the third insulating layer is formed by the plasma treatment that is performed on the second wafer.
